(19) United States
(12) Patent Application Publication
(10) Pub. No.: US 2010/0229928 A1
(43) Pub. Date: Sep. 16, 2010

(54) BACK-CONTACT PHOTOVOLTAIC CELL COMPRISING A THIN LAMINA HAVING A SUPERSTRATE RECEIVER ELEMENT

(75) Inventors: Steven M. Zuniga, Soquel, CA (US); Christopher J. Petti, Mountain View, CA (US); Mohamed M. Hilali, Sunnyvale, CA (US)

Correspondence Address: THE MUELLER LAW OFFICE, P.C., 12951 Harwick Lane, San Diego, CA, 92130, US

(73) Assignee: Twin Creeks Technologies, Inc., San Jose, CA (US)

(21) Appl. No.: 12/403,187

(22) Filed: Mar. 12, 2009

(51) Int. Cl. H01L 31/00; H01L 31/0352

(52) U.S. Cl. 136/255; 136/256; 438/68; 257/E31.032

(57) ABSTRACT

A photovoltaic assembly comprises a thin semiconductor lamina and a receiver element, where the receiver element serves as a superstrate in the completed device. The photovoltaic assembly includes a photovoltaic cell. The photovoltaic cell is a back-contact cell; photocurrent passes into and out of the back surface of the cell, but does not pass through the light-facing surface. The lamina is typically substantially crystalline and has a thickness less than about 100 microns, in some embodiments 10 microns or less.

### BACKGROUND OF THE INVENTION

The invention relates to a photovoltaic cell electrically contacted only at its back surface, the photovoltaic cell comprising a thin semiconductor lamina.

In conventional crystalline photovoltaic cells formed from silicon wafers, the cell is generally thicker than actually required by the device. Making a thinner crystalline cell using conventional methods can be difficult, as thin wafers are prone to breakage. A photovoltaic cell includes an emitter and a base; typically one of the emitter or the base is contacted at the light-facing surface, while the other is contacted at the opposite face. As will be described, methods of forming a thin photovoltaic cell may present challenges in making electrical contact to both the light-facing and back surfaces of the photovoltaic cell.

There is a need, therefore, for a thin photovoltaic cell where electrical contact to both the emitter and base regions is readily made.

### SUMMARY OF THE PREFERRED EMBODIMENTS

The present invention is defined by the following claims, and nothing in this section should be taken as a limitation on those claims. In general, the invention is directed to a photovoltaic assembly comprising a back-contact photovoltaic cell, a thin lamina, and a receiver element serving as a superstrate.

A first aspect of the invention provides for photovoltaic assembly comprising: a semiconductor lamina having a thickness of 50 microns or less, having a first surface and a second surface, the second surface opposite the first; a receiver element, wherein the semiconductor lamina is bonded to the receiver element at the first surface, with zero, one, or more layers intervening; and a photovoltaic cell, wherein the photovoltaic cell comprises the lamina, and wherein, during normal operation of the photovoltaic cell, current flows into and out of the second surface without current flowing through the first surface.

Another aspect of the invention provides for a method for fabricating a photovoltaic assembly, the method comprising: providing a crystalline semiconductor lamina having a first surface, the first surface bonded to a receiver element with zero, one, or more layers intervening, the lamina further having a second surface opposite the first, wherein a thickness between the first surface and the second surface is about 50 microns or less; forming first heavily doped regions of a first conductivity type at the second surface; forming second heavily doped regions of a second conductivity type, electrically opposite the first conductivity type, at the second surface; and fabricating a photovoltaic cell, the photovoltaic cell comprising the lamina.

Each of the aspects and embodiments of the invention described herein can be used alone or in combination with one another.

The preferred aspects and embodiments will now be described with reference to the attached drawings.

### BRIEF DESCRIPTION OF THE DRAWINGS

FIG. 1 is a cross-sectional view showing a prior art photovoltaic cell.

FIGS. 2a-2d are cross-sectional views illustrating stages in formation of a photovoltaic assembly formed by the methods of Sivaram et al., U.S. patent application Ser. No. 12/026,530.

FIG. 3 is a cross-sectional view of a prior art photovoltaic cell electrically contacted only at its back surface.

FIGS. 4a and 4b are cross-sectional views describing fabrication of an embodiment of the present invention.

FIGS. 5a-5f illustrate stages in formation of an embodiment of the present invention. FIGS. 5a-5d and 5f are cross-sectional views, while FIG. 5e is a plan view.

FIGS. 6a and 6b are cross-sectional views illustrating stages in formation of an alternative embodiment of the present invention.

FIGS. 7a through 7f are cross-sectional views illustrating stages in formation of another alternative embodiment of the present invention.

FIG. 8 is a flow diagram illustrating steps that may be carried out to form a photovoltaic cell comprising a thin semiconductor lamina, the lamina contacted only at its back surface, according to embodiments of the present invention.

FIG. 9 is a cross-sectional view showing another embodiment of the present invention.

FIG. 10 is a plan view of a submodule formed according to an embodiment of the present invention.

### DETAILED DESCRIPTION OF THE PREFERRED EMBODIMENTS

A conventional prior art photovoltaic cell includes a p-n diode; an example is shown in FIG. 1. A depletion zone forms at the p-n junction, creating an electric field. Incident photons (incident light is indicated by arrows) will knock electrons from the valence band to the conduction band, creating free electron-hole pairs. Within the electric field at the p-n junction, electrons tend to migrate toward the n region of the diode, while holes migrate toward the p region, resulting in current, called photocurrent. Typically the dopant concentration of one region will be higher than that of the other, so the junction is either a n−/p+ junction (as shown in FIG. 1) or a p−/n+ junction. The more lightly doped region is known as the base of the photovoltaic cell, while the more heavily doped region is known as the emitter. Most carriers are generated within the base, and it is typically the thickest portion of the cell. The base and emitter together form the active region of the cell. The cell also frequently includes a heavily doped contact region in electrical contact with the base, and of the same conductivity type, to improve current flow. In the example shown in FIG. 1, the heavily doped contact region is n-type.

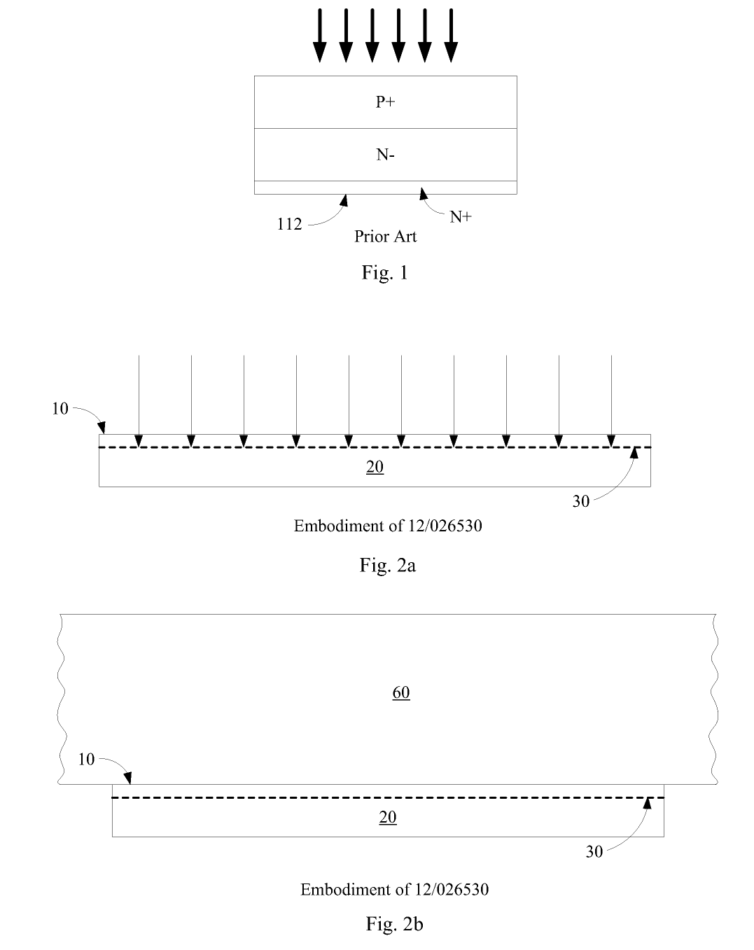

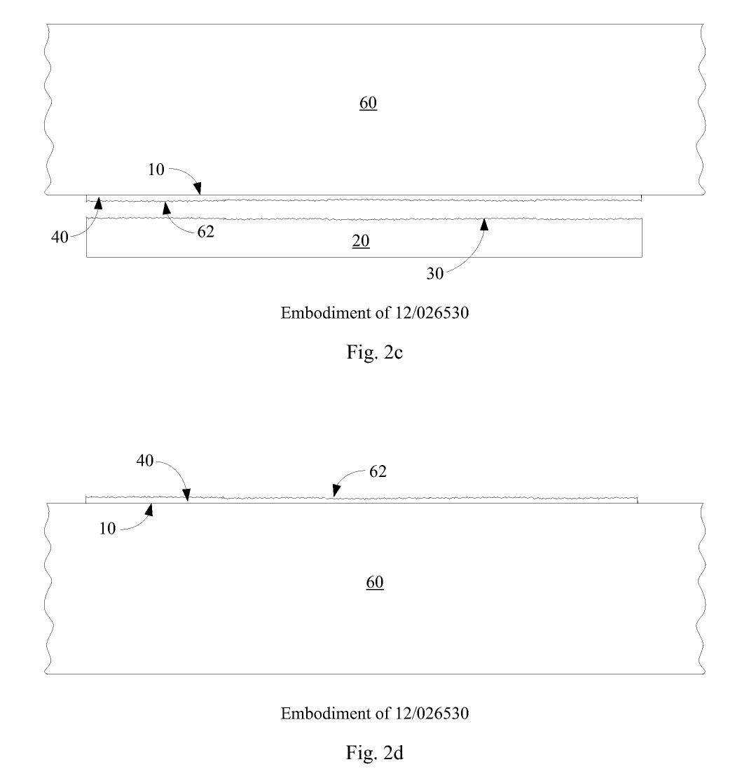

Sivaram et al., U.S. patent application Ser. No. 12/026,530, “Method to Form a Photovoltaic Cell Comprising a Thin Lamina,” filed Feb. 5, 2008, owned by the assignee of the present invention and hereby incorporated by reference, describes fabrication of a photovoltaic cell comprising a thin semiconductor lamina formed of non-deposited semiconductor material. Referring to FIG. 2a, in embodiments of Sivaram et al., a semiconductor donor wafer 20 is implanted with one or more species of gas ions, for example hydrogen and/or helium ions. The implanted ions define a cleave plane 30 within the semiconductor donor wafer. As shown in FIG. 2b, donor wafer 20 is affixed at first surface 10 to receiver 60. Referring to FIG. 2c, an anneal causes lamina 40 to cleave from donor wafer 20 at cleave plane 30, creating second surface 62. In embodiments of Sivaram et al., additional processing before and after the cleaving step forms a photovoltaic cell comprising semiconductor lamina 40, which is between about 0.2 and about 100 microns thick, for example between about 0.2 and about 50 microns, for example between about 1 and about 20 microns thick, in some embodiments between about 1 and about 10 microns thick, though any thickness within the named range is possible. FIG. 2d shows the structure inverted, with receiver 60 at the bottom, as during operation in some embodiments. Receiver 60 may be a discrete receiver element having a maximum width no more than 50 percent greater than that of donor wafer 10, and preferably about the same width, as described in Herner, U.S. patent application Ser. No. 12/057,265, “Method to Form a Photovoltaic Cell Comprising a Thin Lamina Bonded to a Discrete Receiver Element,” filed on Mar. 27, 2008, owned by the assignee of the present application and hereby incorporated by reference.

Using the methods of Sivaram et al., rather than being formed from sliced wafers, photovoltaic cells are formed of thin semiconductor laminae without wasting silicon through excessive kerf loss or by fabrication of an unnecessarily thick cell, thus reducing cost. The same donor wafer can be reused to form multiple laminae, further reducing cost, and may be resold after exfoliation of multiple laminae for some other use.

Once charge carriers are generated in a photovoltaic cell, they must travel to electrical contacts; minority carriers travel to one contact, while majority carriers travel to the other. As free carriers travel through the semiconductor material, they may recombine and be lost to photocurrent. In a conventional cell, like that shown in FIG. 1, with opposing faces doped to opposite conductivity types, photocurrent travels all the way through the cell, entering one face, passing through the cell, and out the opposite face. For good quality silicon, travel distance before recombination is on the order of tens of microns, perhaps 100 microns; this distance is shorter for lower-quality silicon.

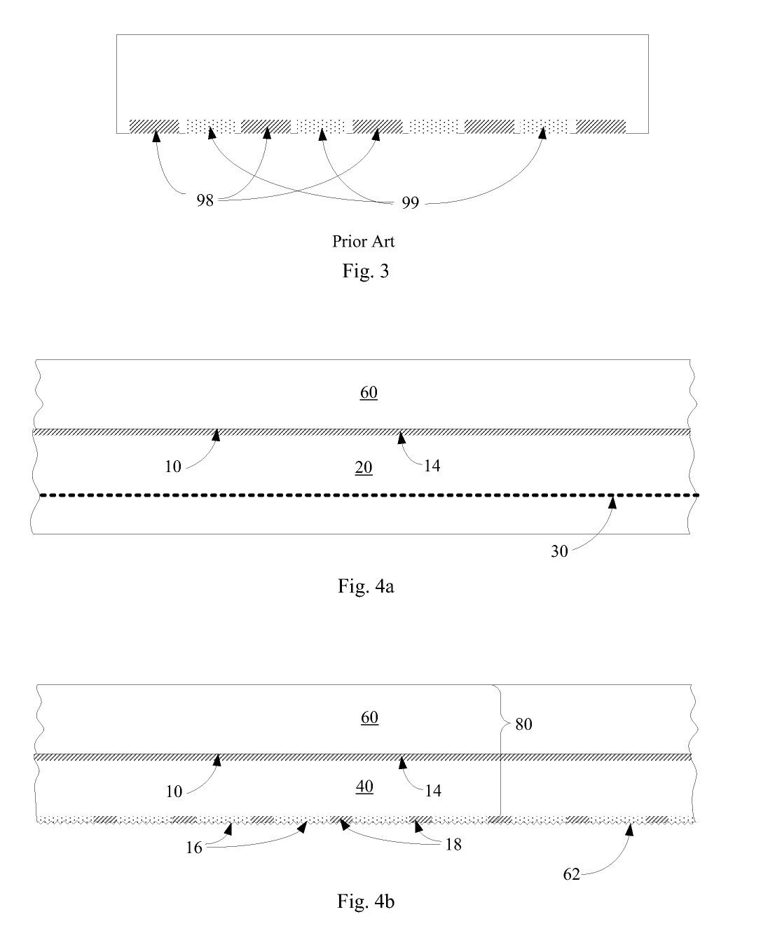

In at least one known cell design, current does not pass from one face to the opposite face. In such a cell, shown in FIG. 3, both heavily doped n-type regions 98 and heavily doped p-type regions 99 are formed at the back surface. During operation of the cell, electrons travel toward n-type regions 98, while holes travel toward p-type regions 99. In such a cell, current passes through only the back face of the cell, not through both faces. In this case a very thick cell is a disadvantage, because free carriers generated near the front surface of the cell are more likely to recombine before they reach the back surface. Thus forming such a cell using the methods of Sivaram et al., which allows a cell to be formed from a thin lamina, may be particularly advantageous.

In a conventional photovoltaic cell, the opposing faces of the cell can be readily accessed during fabrication to form contacts. Completed cells are then mounted onto a supporting substrate or superstrate and electrically connected to form a photovoltaic module. In embodiments of Sivaram et al., though, the wafer must be bonded to a receiver element early in the process in order to provide mechanical support to the thin lamina. A secure bond between the silicon and the receiver element is most effectively achieved with only limited topography between the wafer and the receiver element. Forming wiring at the bonded interface, between the lamina and the receiver element, can be difficult.

In the present invention, a thin semiconductor lamina is formed using the methods of Sivaram et al., and a photovoltaic cell is fabricated from the lamina. The cell has contacts only at the back surface and has a receiver element serving as a superstrate in the completed device. As described, a thin lamina is well-suited to this cell type. Having the receiver element serve as a superstrate means there is no requirement to make electrical contact to the light-facing surface of the lamina, aiding in creation of a secure bond between lamina and receiver element.

Referring to FIG. 4a, donor wafer 20 is made of lightly doped n-type or p-type semiconductor material; in this example wafer 20 is of lightly doped n-type silicon. First surface 10 of wafer 20 is doped to the same conductivity type, forming heavily doped n-type region 14. Gas ions, for example hydrogen and/or helium ions, are implanted through first surface 10 to create cleave plane 30. Wafer 20 is bonded to receiver element 60, which may be any suitable transparent material, such as glass. Receiver element 60 may have a longest dimension no more than about 10 or 20 percent more than the longest dimension of first surface 10 of wafer 20. These surface dimensions may be about the same.

Referring to FIG. 4b, an anneal causes lamina 40 to cleave from the donor wafer at the cleave plane, creating second surface 62. As will be described, heavily doped p-type regions 16 and heavily doped n-type regions 18 are formed at second surface 62. Photovoltaic assembly 80 includes receiver element 60 and lamina 40, and includes a photovoltaic cell. The photovoltaic cell comprises lamina 40.

In embodiments of the present invention, lamina 40 has a thickness of 50 microns or less, for example between about 1 and about 10 microns. Receiver element 60 is bonded to the lamina at first surface 10, with zero, one, or more layers intervening. During normal operation of the photovoltaic cell, current flows into and out of second surface 62, and no current flows through first surface 10. Specifically, current enters lamina 40 at a heavily doped semiconductor region or regions of a first conductivity type at or adjacent to the second surface, and current leaves the lamina at a heavily doped semiconductor region or regions of a second conductivity type at or adjacent to the second surface, the second conductivity type electrically opposite the first conductivity type. Light enters lamina 40 at first surface 10. In the embodiment of FIG. 4b, lamina 40 includes the base of the photovoltaic cell; in most embodiments the lamina includes at least a portion of the base of the photovoltaic cell.

For clarity, a detailed example of a photovoltaic assembly including a receiver element and a lamina having thickness between 0.2 and 100 microns, in which photocurrent passes only through the back surface of the lamina, and in which the receiver element serves as a superstrate, according to embodiments of the present invention, will be provided. For completeness, many materials, conditions, and steps will be described. It will be understood, however, that many of these details can be modified, augmented, or omitted while the results fall within the scope of the invention. In these embodiments, it is described to cleave a semiconductor lamina by implanting gas ions and exfoliating the lamina. Other methods of cleaving a lamina from a semiconductor wafer could also be employed in these embodiments.

### Example

### Back Contact Cell with Doping

The process begins with a donor body of an appropriate semiconductor material. An appropriate donor body may be a monocrystalline silicon wafer of any practical thickness, for example from about 200 to about 1000 microns thick. In alternative embodiments, the donor wafer may be thicker; maximum thickness is limited only by practicalities of wafer handling. Alternatively, polycrystalline or multicrystalline silicon may be used, as may microcrystalline silicon, or wafers or ingots of other semiconductors materials, including germanium, silicon germanium, or III-V or II-VI semiconductor compounds such as GaAs, InP, etc. In this context the term multicrystalline typically refers to semiconductor material having grains that are on the order of a millimeter or larger in size, while polycrystalline semiconductor material has smaller grains, on the order of a thousand angstroms. The grains of microcrystalline semiconductor material are very small, for example 100 angstroms or so. Microcrystalline silicon, for example, may be fully crystalline or may include these microcrystals in an amorphous matrix. Multicrystalline or polycrystalline semiconductors are understood to be completely or substantially crystalline.

The process of forming monocrystalline silicon generally results in circular wafers, but the donor body can have other shapes as well. Cylindrical monocrystalline ingots are often machined to an octagonal cross section prior to cutting wafers. Multicrystalline wafers are often square. Square wafers have the advantage that, unlike circular or hexagonal wafers, they can be aligned edge-to-edge on a photovoltaic module with minimal unused gaps between them. The diameter or width of the wafer may be any standard or custom size. For simplicity this discussion will describe the use of a monocrystalline silicon wafer as the semiconductor donor body, but it will be understood that donor bodies of other types and materials can be used.

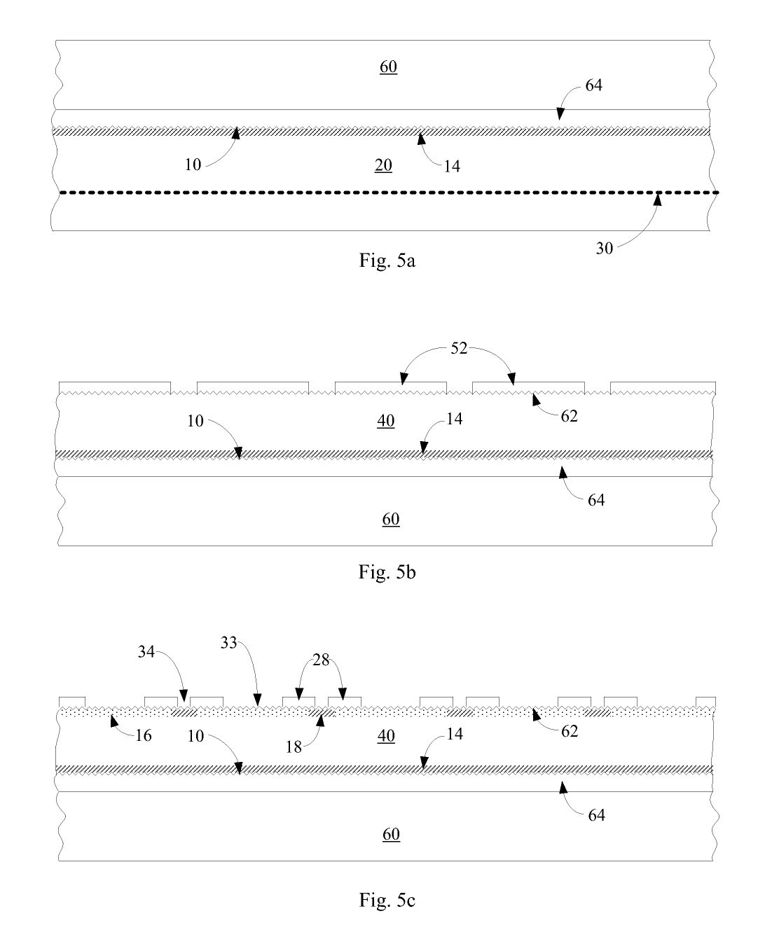

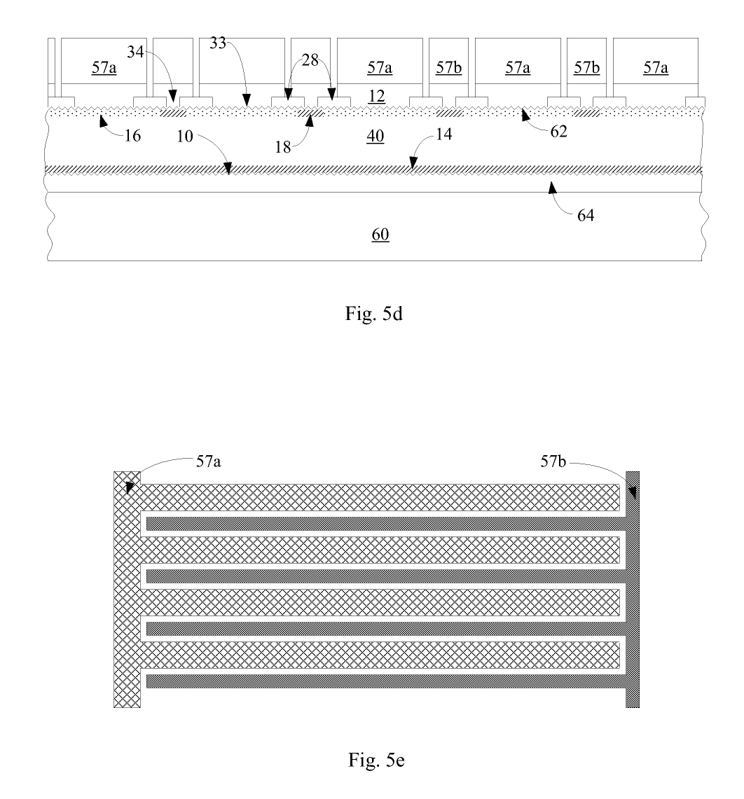

Referring to FIG. 5a, donor wafer 20 is a monocrystalline silicon wafer which is lightly to moderately doped to a first conductivity type. The present example will describe a relatively lightly n-doped wafer 20 but it will be understood that in this and other embodiments the dopant types can be reversed. Wafer 20 may be doped to a concentration of between about 1×10¹⁶ and about 1×10¹⁸ dopant atoms/cm³, for example about 1×10¹⁷ dopant atoms/cm³. The fact that donor wafer 20 can be reused for some other purpose following exfoliation of one or more laminae makes the use of higher-quality silicon economical. Donor wafer 20 may be semiconductor-grade silicon, rather than solar-grade silicon, for example.

First surface 10 of donor wafer 20 may be substantially planar, or may have some preexisting texture. If desired, some texturing or roughening of first surface 10 may be performed, for example by wet etch or plasma treatment. Surface roughness may be random or may be periodic, as described in “Niggeman et al., “Trapping Light in Organic Plastic Solar Cells with Integrated Diffraction Gratings,” Proceedings of the 17^{th} European Photovoltaic Solar Energy Conference, Munich, Germany, 2001. Methods to create surface roughness are described in further detail in Petti, U.S. patent application Ser. No. 12/130,241, “Asymmetric Surface Texturing For Use in a Photovoltaic Cell and Method of Making,” filed May 30, 2008; and in Herner, U.S. patent application Ser. No. 12/343,420, “Method to Texture a Lamina Surface Within a Photovoltaic Cell,” filed Dec. 23, 2008, both owned by the assignee of the present application and both hereby incorporated by reference.

First surface 10 may be heavily doped to some depth to the same conductivity type as wafer 20, forming heavily doped region 14; in this example, heavily doped region 14 is n-type. As wafer 20 has not yet been affixed to a receiver element, high temperatures can readily be tolerated at this stage of fabrication, and this doping step can be performed by any conventional method, including diffusion doping. Any conventional n-type dopant may be used, such as phosphorus or arsenic. Dopant concentration may be as desired, for example at least 1×10¹⁸ dopant atoms/cm³, for example between about 1×10¹⁸ and 1×10²¹ dopant atoms/cm³. Doping and texturing can be performed in any order, but since most texturing methods remove some thickness of silicon, it may be preferred to form heavily doped n-type region 14 following texturing. Doping is followed by conventional deglazing.

In the next step, ions, preferably hydrogen or a combination of hydrogen and helium, are implanted through dielectric layer 64 into wafer 20 to define cleave plane 30, as described earlier. The cost of this hydrogen or helium implant may reduced by methods described in Parrill et al., U.S. patent application Ser. No. 12/122,108, “Ion Implanter for Photovoltaic Cell Fabrication,” filed May 16, 2008, owned by the assignee of the present invention and hereby incorporated by reference. The overall depth of cleave plane 30 is determined by several factors, including implant energy. The depth of cleave plane 30 can be between about 0.2 and about 100 microns from first surface 10, for example between about 0.5 and about 20 or about 50 microns, for example between about 1 and about 10 microns or between about 1 or 2 microns and about 5 microns.

An antireflective coating (ARC) layer 64 is formed on first surface 10. Any suitable material may be used, such as silicon nitride, which may be, for example, between about 700 and about 800 angstroms thick. In other embodiments silicon dioxide may be used for ARC 64, or ARC 64 may be a stack of silicon nitride and silicon dioxide. As will be seen, this layer will bond to glass; it may be found that a thin layer of silicon dioxide, for example about 200 angstroms, formed on a silicon nitride layer may aid bonding. Both ARC 64 and the optional silicon dioxide layer may be formed by plasma enhanced chemical vapor deposition (PECVD), in general at 350 degrees C. or less.

Next donor wafer 20 is bonded to receiver element 60 with ARC 64 disposed between them, for example by anodic bonding. Receiver element 60 will serve as a superstrate in the completed cell and thus must be transparent. Any suitable transparent material may be used for receiver element 60, such as soda-lime glass, or a heat-resistant glass such as borosilicate glass.

Referring to FIG. 5b, a thermal step causes lamina 40 to cleave from the donor wafer at the cleave plane. FIG. 5b shows the structure inverted, with receiver element 60 on the bottom, as it may be during fabrication. In some embodiments, this cleaving step may be combined with bonding. Cleaving is achieved in this example by exfoliation, which may be performed at temperatures between, for example, about 350 and about 650 degrees C. In general exfoliation proceeds more rapidly at higher temperature. The thickness of lamina 40 is determined by the depth of cleave plane 30. In many embodiments, the thickness of lamina 40 is between about 1 and about 10 microns, for example between about 2 and about 5 microns. Bonding and exfoliation may be achieved using methods described in Agarwal et al., U.S. patent application Ser. No. 12/335,479, “Methods of Transferring a Lamina to a Receiver Element,” filed Dec. 15, 2008, owned by the assignee of the present application and hereby incorporated by reference.

Second surface 62 has been created by exfoliation. Sufficient texturing or roughness may exist at second surface 62 upon exfoliation. If desired, an additional texturing step may be performed at second surface 62 by any of the methods described earlier. Such a texturing step may serve to remove damage at second surface 62. A specific damage-removal step may be performed, for example by etch or plasma treatment. Damage removal and texturing may be combined into a single step, or may be separate steps.

Next a doped glass layer 52 is formed on second surface 62, for example by atmospheric pressure chemical vapor deposition. In this example doped glass layer 52 is borosilicate glass, doped with boron, a p-type dopant. The source gas may be any suitable gas that will provide boron, for example, BBr₃, B₂H₆, or BCl₃. In other embodiments, a dopant-providing material may be spun onto second surface 62 and baked. In still other embodiments, the doped glass may be grown thermally, by flowing O₂ over a solid boron source such as BN. The doped glass may have a thickness between, for example, about 500 and about 1500 angstroms, for example about 1000 angstroms. Next the BSG 52 is removed in selected areas, preferably in a stripe pattern, for example by screen printing etchant paste, to expose second surface 62 in regions between remaining BSG regions 52.

Turning to FIG. 5c, heavily doped n-type regions 18 are formed at the exposed regions of second surface 62. This may be done by any appropriate method, for example by flowing POCl at about 880 degrees C. for about 30 minutes, forming phosphosilicate glass (PSG, not shown) at the exposed regions of second surface 62. An anneal, for example between about 850 and about 1000 degrees C., performed in a furnace from between about 30 and about 90 minutes, diffuses dopants from both the BSG and PSG regions into lamina 40 at second surface 62, forming heavily doped p-type regions 16 beneath BSG regions 52 and heavily doped n-type regions 18 between them. Note that heavily doped n-type regions 18 and heavily doped p-type regions 16 are touching. This is acceptable so long as the dopant profiles are optimized accordingly. For example, the boron concentration should only be as high as required to form an effective emitter. This may be achieved by, for example, limiting the temperature of the diffusion step to between about 850 and about 900 degrees C.

Next a conventional wet etch, for example an HF dip, removes the BSG and PSG, leaving heavily doped n-type regions 18 and heavily doped p-type regions 16 exposed at second surface 62. Boron and phosphorus are the most commonly used p-type and n-type dopants, respectively, but other dopants may be used.

Next a dielectric layer 28, for example silicon nitride, is deposited on second surface 62, for example by PECVD. The thickness of layer 28 may be as desired, for example about 1000 angstroms. Openings 33 and 34 are formed in silicon nitride layer 28 by any suitable method. In some embodiments these openings are formed using screen print resist followed by etching, or screen print etch paste. Each opening 33 exposes a central portion of one of the heavily doped p-type regions 16, while each opening 34 exposes a central portion of one of the heavily doped n-type regions 18.

Next electrical contact will be made to heavily doped n-type regions 18 and heavily doped p-type regions 16. Turning to FIG. 5d, metal layer 12 is deposited, for example by sputtering, onto silicon nitride layer 28 and the portions of heavily doped p-type regions 16 exposed in openings 33 and heavily doped n-type regions 18 exposed in openings 34. Metal layer 12 will serve as a reflector at the back of lamina 40 in the completed photovoltaic cell, so the material used is preferably a good reflector. For example, metal layer 12 may be aluminum or silver, or may be a stack of metals, for example aluminum and titanium nitride or titanium tungsten. Gaps are formed in metal layer 12 by any suitable method, such as screen print resist paste or etch paste. Finally wiring is formed, for example by electroplating copper, after deposition of a suitable barrier layer and seed layer. Following electroplating, a solderable layer may be formed on the copper, as will be understood by those skilled in the art. Fingers 57a contact p-doped regions 16, while fingers 57b contact n-doped regions 18. To improve resistance, wiring 57a and 57b may be relatively thick (thickness here refers to the dimension perpendicular to second surface 62), for example about 40 microns.

In the completed photovoltaic cell shown, heavily doped p-type regions 16 behave as the emitter of the cell. A p-n junction exists between each heavily doped p-type region 16 and the base region of the cell, which is the remainder of lightly n-doped lamina 40. Heavily doped n-type regions 18 serve as contacts to the base region. Wiring 57a and 57b may be in the form of interdigitated fingers, as depicted in plan view in FIG. 5e, with fingers 57a contacting p-doped regions 16, and fingers 57b contacting n-doped regions 18.

Surface dimensions of doped regions 16 and 18 may be selected based on their function, and may vary depending on various cell characteristics, including the thickness of the lamina, the resistivity of the base region, the methods used to form features, etc. Generally the emitter regions, heavily doped p-type regions 16, will be wider than the contact regions 18. This may be preferred for a variety of reasons, including the fact that narrower contact regions will decrease the maximum travel distance for minority carriers, thus maximizing the number of generated minority carriers that are collected. For example, referring to FIG. 5d, in a completed cell, a hole generated in the base region near first surface 10 across from the midpoint of an n-doped region 18 must travel laterally half of the width of the base contact region, which is typically much greater than the lamina thickness, to be collected as photocurrent at one of adjacent p-regions 16. The longer this distance, the higher the probability that the hole will recombine before it can reach wiring 57. In one embodiment, the surface width of heavily doped n-type regions 18 is about 280 microns, while width of heavily doped p-type regions 16 is about 1320 microns, for a pitch of about 1600 microns. The gaps in silicon nitride layer 28 exposing n-type regions 18 may be about 120 microns wide, while gaps in silicon nitride layer 28 exposing p-type regions 16 may be about 920 microns wide. The width of fingers 57a contacting p-doped regions 16 may be about 280 microns, the width of fingers 57b contacting n-doped regions 18 may be about 1020 microns, with gaps of about 120 microns separating them. Clearly these are only examples, and dimensions may be changed as desired.

FIG. 5f shows a completed photovoltaic assembly 80. The structure is inverted, with receiver element 60 at the top, as during operation. A plurality of photovoltaic assemblies 80 can be mounted on a supporting substrate 90, as shown, and electrically connected in series, forming a photovoltaic module. Photovoltaic assembly 80 comprises lamina 40 and receiver element 60. In this embodiment, a photovoltaic cell is included within lamina 40. Incident light, indicated by arrows, enters lamina 40 at first surface 10, and is reflected back into lamina 40 at second surface 62. Current flows into and out of lamina 40 at second surface 62, and does not pass through first surface 10.

### Example

### Laser Doping

Referring to FIG. 5f, use of high processing temperature at second surface 62 to form doped regions 16 and 18 may call for use of materials such as borosilicate glass, which can tolerate high temperature, for receiver element 60. In an alternative embodiment, these heavily doped regions can be formed by lower-temperature methods, possibly allowing the use of less-expensive materials for receiver element 60 which are less tolerant of high temperature, such as soda-lime glass.

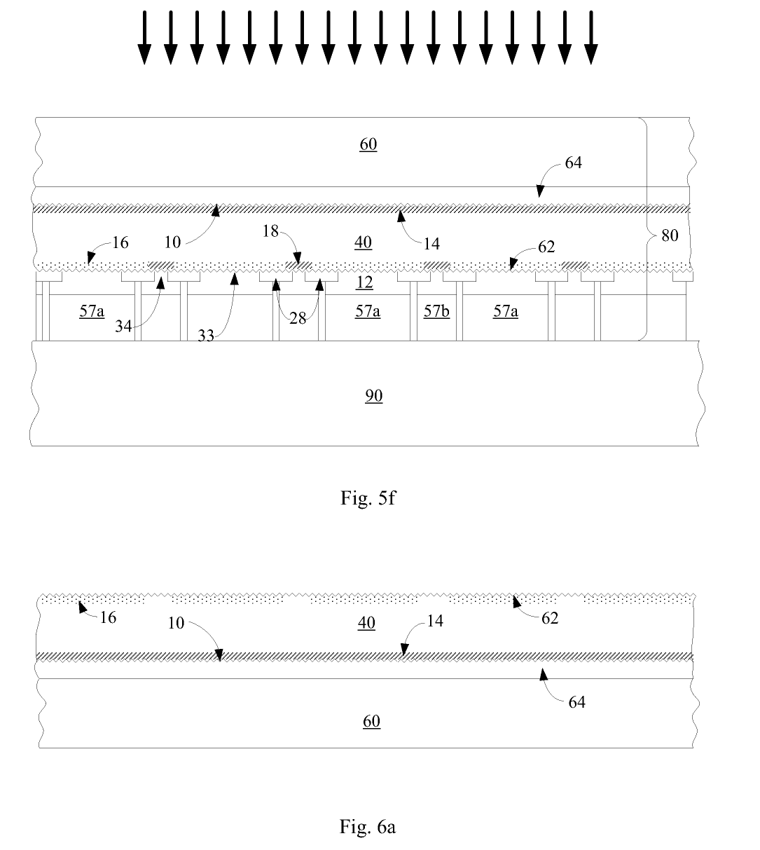

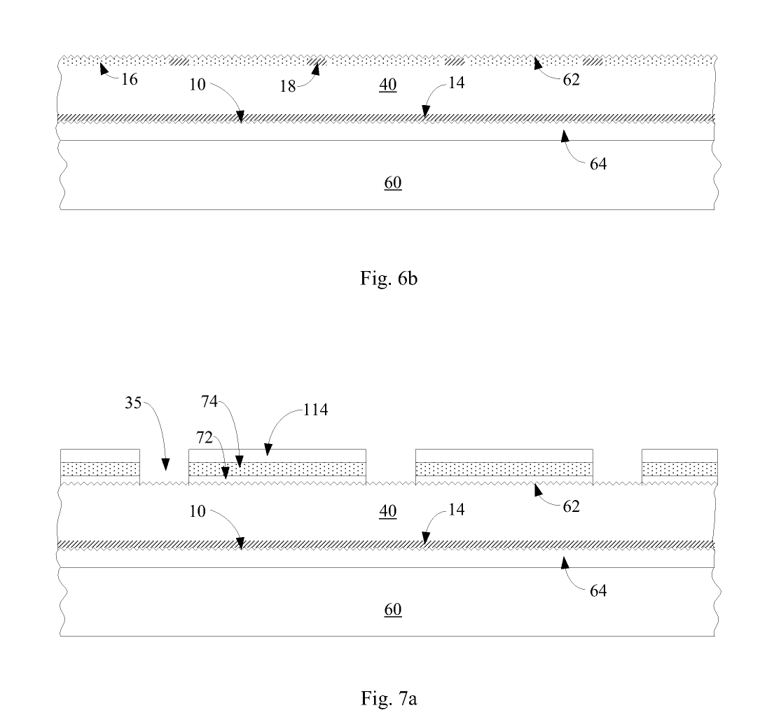

Turning to FIG. 6a, in one low-temperature embodiment, fabrication proceeds as in the prior example to the point at which lamina 40 is exfoliated from the donor wafer, creating second surface 62, which is then optionally textured and treated to remove damage. In this example, lamina 40 is lightly n-doped, though in this embodiment, as in all embodiments, conductivity types may be reversed.

At this point in the process, instead of depositing a doped glass as in the prior example, a material that will provide a p-type dopant, such as BSG, is sprayed or spun onto second surface 62 and cured, for example at about 200 degrees C. Next the spun-on BSG (not shown) is scanned with a laser in a stripe pattern, forming heavily doped p-type regions 16 with undoped gaps between them. This laser treatment heats only the surface 62 and a very short distance beneath it, but does not expose receiver element 60, or the bond between receiver element 60 and lamina 40, to high temperature.

Next a deglazing step removes the spun-on BSG. A material that will provide an n-type dopant, such as PSG (not shown), is sprayed or spun onto second surface 62 and cured. Referring to FIG. 6b, spun-on PSG is again scanned with a laser in the undoped areas, forming heavily doped n-type regions 18 alternating with heavily doped p-type regions 16. Another deglazing step removes the PSG. Fabrication continues as in the prior embodiment, depositing a dielectric on second surface 62 and forming contacts through openings in the dielectric to the heavily doped p-type regions 16 and heavily doped n-type regions 18 just formed. In this embodiment, it may be preferred to limit the laser scan during laser doping to leave a small gap between each heavily doped p-type region 16 and adjacent heavily doped n-type regions 18.

### Example

### Amorphous Doped Regions

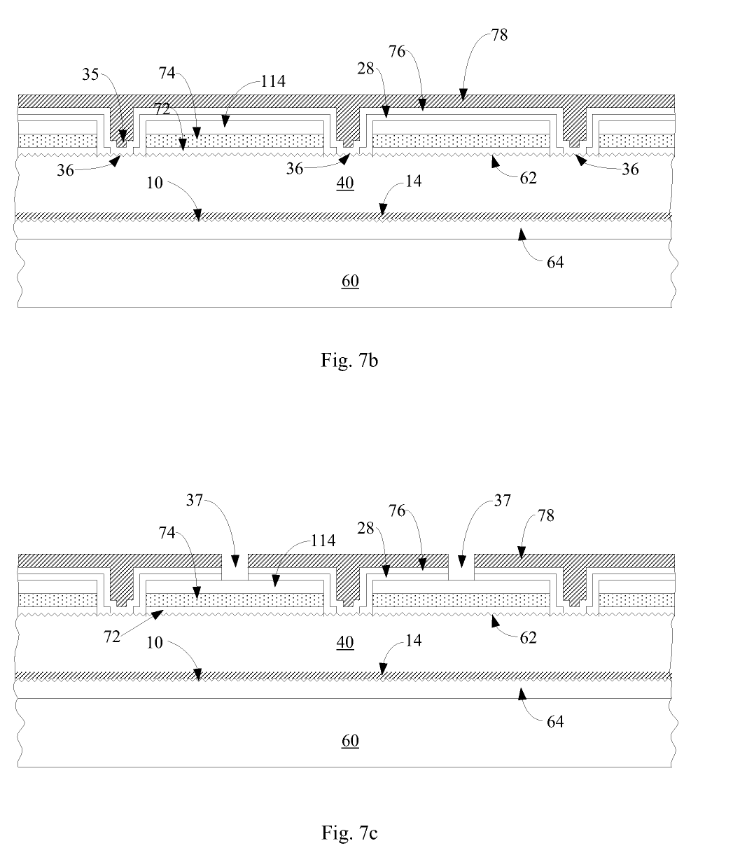

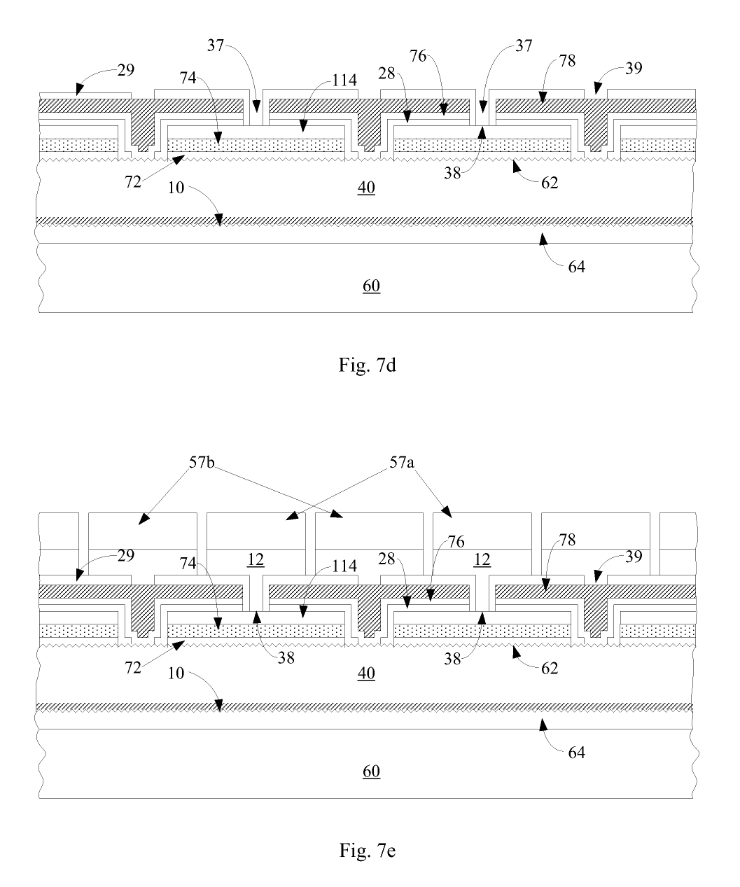

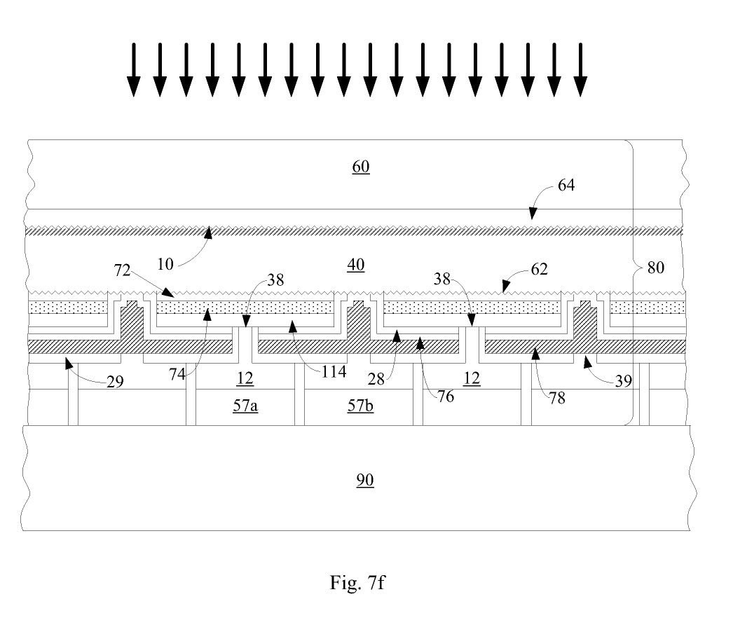

In an alternative low-temperature embodiment, heavily doped n-type and p-type regions are formed at the back surface of the lamina by depositing heavily doped amorphous silicon. Turning to FIG. 7a, fabrication proceeds as in prior embodiments to the point at which lamina 40, already bonded to receiver element 60, is cleaved from the donor wafer, creating second surface 62. Heavily doped n-type region 14 was previously formed at first surface 10. In this example, lamina 40 is lightly n-doped. FIG. 7a shows receiver element 60 on the bottom, as during fabrication. As in prior embodiments, second surface 62 is optionally textured and treated to remove damage.

Next a thin layer 72 of intrinsic amorphous silicon may be deposited. This layer serves to passivate second surface 62, and should be thin, for example 50 angstroms or less, for example about 15, 20, or 30 angstroms. In some embodiments, amorphous intrinsic layer 72 may be omitted.

A layer 74 of heavily doped p-type amorphous silicon is deposited on intrinsic amorphous layer 72, or directly on second surface 62 if layer 72 was omitted. Deposition of p-doped amorphous layer 74 can be performed by PECVD at relatively low temperature, for example below about 500 degrees C., in some cases below about 350 degrees C., for example, at about 250 degrees C. or below. A source gas to provide a p-type dopant, such as boron, is flowed during deposition, doping the silicon as it is deposited. Heavily doped p-type amorphous silicon layer 74 may be about 70 angstroms thick or more.

Next metal layer 114 is deposited. This layer should be conductive and preferably is also reflective; thus aluminum or silver may be a good choice. A TCO layer (not shown) may optionally be included between amorphous silicon layer 74 and metal layer 114. Metal layer 114 may be formed by any suitable method, for example sputtering or evaporation, and may be between about 1000 and about 1500 angstroms thick.

Openings 35, which may be in the form of substantially parallel stripes, are formed in aluminum layer 114, heavily doped p-type amorphous layer 74, and intrinsic amorphous layer 72, exposing lamina 40 at second surface 62. The width of these stripes may be as desired; in one embodiment openings 35 may be about 280 microns wide and formed at a pitch of about 1600 microns. Openings 35 may be formed by any suitable method, for example screen printing or laser ablation. During creation of openings 35 a small thickness of lamina 40 may inadvertently be removed in the openings, which is readily tolerated.

Turning to FIG. 7b, a layer 28 of a dielectric, for example silicon nitride, is formed next, for example by PECVD at temperatures of about 250 degrees C. or below. This layer may be about 1000 to about 2000 angstroms thick. Openings 36 are formed in silicon nitride layer 28, exposing the surface of lamina 40. Openings 36 are formed within prior openings 35 and are in the form of stripes. Openings 36 may be formed by any suitable method, for example by laser ablation or screen printing an etchant paste, and may be any suitable width, for example about 120 microns.

Next intrinsic amorphous silicon layer 76, of about the same thickness as intrinsic amorphous silicon layer 72, is deposited on silicon nitride layer 28, contacting lamina 40 in openings 36. Intrinsic amorphous silicon layer 76 may be omitted. Heavily doped n-type amorphous silicon layer 78, typically at least 70 angstroms thick, is deposited on intrinsic amorphous silicon layer 76, or on silicon nitride layer 28 and directly contacting lamina 40 in openings 36 if intrinsic amorphous silicon layer 76 was omitted.

Next, referring to FIG. 7c, openings 37 are formed in heavily doped n-type amorphous layer 78, intrinsic amorphous layer 76, and silicon nitride layer 28, exposing aluminum layer 114. Openings 37 may be holes, rather than stripes, and may have a width, for example, of about 175 microns, if formed by laser ablation, or about 360 microns, if formed by screen printing.

Turning to FIG. 7d, layer 29 of a dielectric, for example silicon nitride, is deposited, for example by PECVD. In some embodiments, silicon nitride layer 29 may be about 1000 angstroms thick. Openings 38 and 39 are formed in silicon nitride layer 29, for example by laser ablation or screen printing. Openings 38 are holes, and expose aluminum layer 114 in the openings 37 formed in the previous step. Openings 39 are stripes, and expose heavily doped n-type amorphous layer 78.

As shown in FIG. 7e, a metal layer 12 is formed, for example by sputtering. Metal layer 12 may be any suitable conductive material, preferably a reflective metal such as aluminum or silver, or a stack of metal such as aluminum and titanium nitride or titanium tungsten. A suitable barrier layer, for example titanium tungsten or titanium nitride, is formed on metal layer 12, followed by a seed layer for an electroplating step to follow.

As in prior embodiments, gaps are formed in metal layer 12, and the barrier and seed layers, by any suitable method, such as screen print resist paste, etch paste, or laser ablation. Finally wiring 57, consisting of fingers 57a and 57b, is formed, for example by electroplating copper. As in prior embodiments, fingers 57a contact the heavily doped p-type region, in this embodiment layer 74 by way of aluminum layer 114; and fingers 57b contact the heavily doped n-type region, in this embodiment layer 78, which is in turn in electrical contact with the base region, lightly doped lamina 40. To improve resistance, wiring 57 may be relatively thick (thickness here refers to the dimension perpendicular to second surface 62), for example about 40 microns. All dimensions provided here are examples only, and can be modified. Note that drawings are not to scale.

FIG. 7f shows the completed photovoltaic assembly 80, which includes lamina 40 and receiver element 60. The structure is shown inverted, with receiver element at the top, as during operation. A photovoltaic cell is formed by lamina 40, which comprises the lightly doped n-type base region, heavily doped p-type amorphous regions 74, which form the emitter of the cell, and heavily doped n-type amorphous regions 78, which provide electrical contact to the base of the cell. In prior embodiments, heavily doped n-type and p-type regions were formed at second surface 62 by doping a portion of lamina 40; in this embodiment heavily doped n-type and p-type regions are formed adjacent to second surface 62 by depositing heavily doped amorphous silicon. As shown, this photovoltaic assembly 80 may be affixed to a supporting substrate 90 along with other photovoltaic assemblies 80, the photovoltaic cells of each assembly connected in series, forming a photovoltaic module. Incident light, indicated by arrows, enters photovoltaic assembly 80 at receiver element 60, which serves as a superstrate, enters lamina 40 at first surface 10 (the light-facing surface), and is reflected back into lamina 40 at second surface 62 (the back surface). In other embodiments, photovoltaic assemblies may be affixed to a supporting superstrate (not shown).

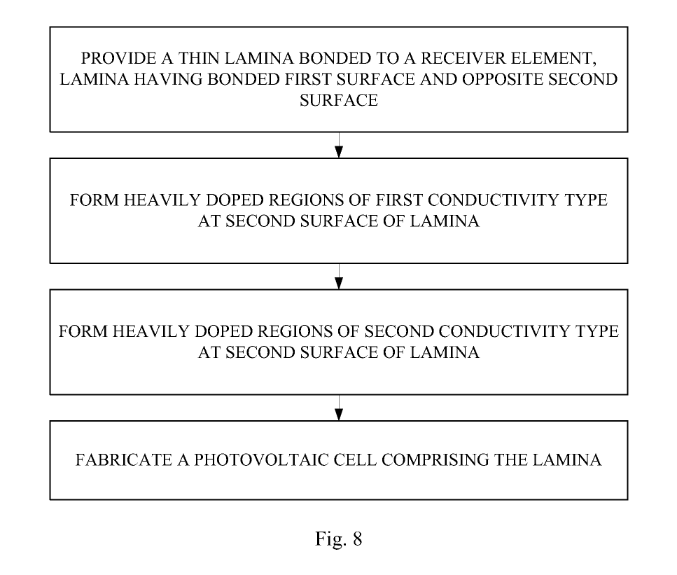

In general, a method has been described for method for fabricating a photovoltaic assembly, the method comprising: providing a crystalline semiconductor lamina having a first surface, the first surface bonded to a receiver element with zero, one, or more layers intervening, the lamina further having a second surface opposite the first, wherein a thickness between the first surface and the second surface is about 50 microns or less; forming first heavily doped regions of a first conductivity type at the second surface; forming second heavily doped regions of a second conductivity type, electrically opposite the first conductivity type, at the second surface; and fabricating a photovoltaic cell, the photovoltaic cell comprising the lamina. As described, the heavily doped regions may be formed by a variety of methods. In two of the examples given, laser doping and deposition of heavily doped amorphous silicon, processing temperature does not exceed about 500 degrees C. following the cleaving step, and in some cases will not exceed about 450 degrees C. following the cleaving step. The crystalline semiconductor lamina bonded to the receiver element may be formed by forming a cleave plane in a donor body, bonding the donor body to the receiver element, then cleaving the lamina from the donor body at the cleave plane, as described earlier. This method is summarized in FIG. 8.

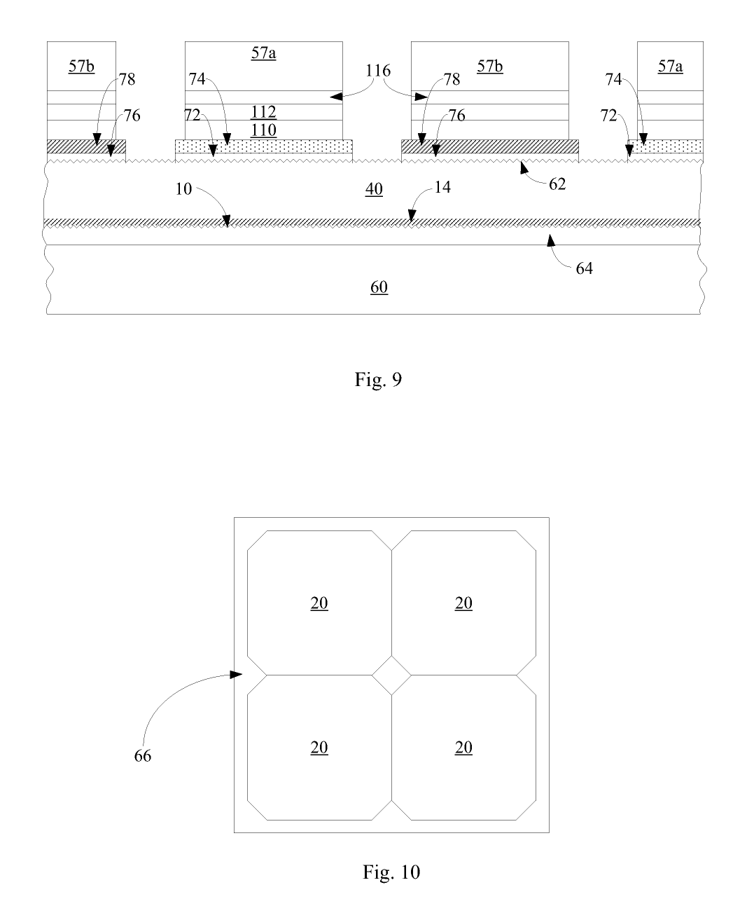

In another variation on a low-temperature embodiment, turning to FIG. 9, lightly doped n-type lamina 40 is bonded to receiver element 60 with ARC 64 between them. Heavily doped n-type region 14 was formed at first surface 10 prior to bonding. Receiver element 60 may be any suitable material, for example soda-lime glass. Using a shadow mask, intrinsic amorphous silicon regions 76 are optionally formed, followed by heavily doped n-type amorphous silicon regions 78 in the same areas. In some embodiments, intrinsic amorphous silicon regions 76 may be omitted. A second mask is applied, and intrinsic amorphous silicon regions 72 are formed, followed by heavily doped p-type amorphous silicon regions 74, again in the same areas. The p-doped regions 74 alternate on second surface 62 with n-doped regions 78. Thicknesses of these layers may be as described in the low-temperature embodiment of FIG. 7f. The shadow masks can be arranged such that adjacent amorphous silicon regions having opposite conductivity types do not touch. A TCO layer 110, for example between about 1000 and about 1200 angstroms thick, is deposited on the entire structure, for example by sputtering, followed by a suitable barrier layer 112 such as titanium nitride or titanium tungsten. Barrier layer 112 may be, for example, about 3000 angstroms thick. A copper seed layer 116, which may be about 1000 angstroms thick, is deposited as well.

Next the copper seed layer 116, barrier layer 112, and TCO 110 are patterned, for example using screen print etchant paste, as shown, such that the contacts to adjacent heavily doped n-type regions 78 and heavily doped p-type regions 74 are isolated from each other. As shown, the dimensions of the gaps in copper seed layer 116, barrier layer 112 and TCO 110 may be chosen to be slightly larger than the gaps between adjacent amorphous silicon regions to aid in alignment. Screen print resist paste is printed such that resist fills the gaps between adjacent regions of copper seed layer 116, barrier layer 112, and TCO 110. Wiring 57a, contacting p-doped amorphous silicon regions 74, and wiring 57b, contacting n-doped amorphous silicon regions 78, are formed, for example by electroplating copper, and the screen print resist paste is stripped.

Alternatively, following deposition of TCO 110, barrier layer 112, and copper seed layer 116, screen print resist paste can be printed such that resist paste remains in the areas between the amorphous regions, where copper wiring is not to be formed. Electroplating forms copper wiring 57a and 57b. After the resist paste is stripped, wiring 57a and 57b is used as a hard mask during etch of copper seed layer 116, barrier layer 112, and TCO 110, yielding the structure of FIG. 9.

As in prior embodiments, the structure will be inverted in the completed cell, with receiver element 60 serving as a superstrate during operation.

In the embodiments described so far, the receiver element has about the same surface dimensions as the donor wafer, and a single donor wafer is bonded to a single receiver element. In some embodiments, it may be preferred to bond more than one donor wafer to a single receiver element, where the single receiver element is substantially larger than the donor wafers. For example, FIG. 10 shows four donor wafers 20 bonded to a single receiver element 66. Following exfoliation, four laminae will be exfoliated from the donor wafers and will remain bonded to receiver element 66. This submodule may be combined with other submodules to form a photovoltaic module. Other numbers of lamina may make up the submodule; for example it may include three, six, eight, or some other number of laminae.

A variety of embodiments has been provided for clarity and completeness. Clearly it is impractical to list all possible embodiments. Other embodiments of the invention will be apparent to one of ordinary skill in the art when informed by the present specification. Detailed methods of fabrication have been described herein, but any other methods that form the same structures can be used while the results fall within the scope of the invention.

The foregoing detailed description has described only a few of the many forms that this invention can take. For this reason, this detailed description is intended by way of illustration, and not by way of limitation. It is only the following claims, including all equivalents, which are intended to define the scope of this invention.

What is claimed is:

1. A photovoltaic assembly comprising:
a semiconductor lamina having a thickness of 50 microns or less, having a first surface and a second surface, the second surface opposite the first;
a receiver element, wherein the semiconductor lamina is bonded to the receiver element at the first surface, with zero, one, or more layers intervening; and
a photovoltaic cell, wherein the photovoltaic cell comprises the lamina, and wherein,
during normal operation of the photovoltaic cell, current flows into and out of the second surface without current flowing through the first surface.

2. The photovoltaic assembly of claim 1 wherein the thickness of the semiconductor lamina is between about 1 and about 10 microns.

3. The photovoltaic assembly of claim 1 wherein, during normal operation of the photovoltaic cell, incident light enters the semiconductor lamina at the first surface.

4. The photovoltaic assembly of claim 1 wherein the receiver element comprises glass.

5. The photovoltaic assembly of claim 4 wherein the receiver element comprises soda-lime glass.

6. The photovoltaic assembly of claim 1 wherein the longest dimension of the receiver element is no more than about 10 percent more than the longest dimension of the first surface.

7. The photovoltaic assembly of claim 1 wherein the semiconductor lamina comprises at least a portion of a base of the photovoltaic cell.

8. The photovoltaic assembly of claim 1 wherein, during normal operation of the photovoltaic cell, current enters the lamina at a heavily doped semiconductor region or regions of a first conductivity type at or adjacent to the second surface, and current leaves the lamina at a heavily doped semiconductor region or regions of a second conductivity type at or adjacent to the second surface, the second conductivity type electrically opposite the first conductivity type.

9. The photovoltaic assembly of claim 8 wherein the heavily doped semiconductor region or regions of the first conductivity type, or of the second conductivity type, or both, comprise amorphous silicon.

10. The photovoltaic assembly of claim 1 wherein the semiconductor lamina is crystalline silicon.

11. The photovoltaic assembly of claim 1 wherein the semiconductor lamina is monocrystalline silicon.

12. A method for fabricating a photovoltaic assembly, the method comprising:
providing a crystalline semiconductor lamina having a first surface, the first surface bonded to a receiver element with zero, one, or more layers intervening, the lamina further having a second surface opposite the first, wherein a thickness between the first surface and the second surface is about 50 microns or less;
forming first heavily doped regions of a first conductivity type at the second surface;
forming second heavily doped regions of a second conductivity type, electrically opposite the first conductivity type, at the second surface; and
fabricating a photovoltaic cell, the photovoltaic cell comprising the lamina.

13. The method of claim 13 wherein the thickness of the semiconductor lamina between the first and second surfaces is between about 0.5 and about 20 microns.

14. The method of claim 12 wherein the step of providing the crystalline semiconductor lamina comprises:
affixing a semiconductor donor body to the receiver element at a first surface of the semiconductor donor body, with zero, one, or more layers intervening; and
cleaving the semiconductor lamina from the donor body at a cleave plane, creating the second surface of the semiconductor lamina opposite the first surface, wherein the lamina remains affixed to the receiver element;

15. The method of claim 14 further comprising, before the affixing step, defining the cleave plane in the semiconductor donor body by implanting gas ions.

16. The method of claim 15 wherein the gas ions comprise hydrogen and/or helium ions.

17. The method of claim 14 wherein the semiconductor donor body is a monocrystalline silicon wafer.

18. The method of claim 12 wherein the receiver element comprises glass.

19. The method of claim 12 wherein, after the cleaving step, processing temperature does not exceed about 450 degrees C.
